(19) United States
(12) Patent Application Publication
(10) Pub. No.: US 2018/0048277 A1
(43) Pub. Date: Feb. 15, 2018

(54) METHOD FOR SYNCHRONIZING LEFT AND RIGHT CHANNELS IN SMART AUDIO AMPLIFIERS

(71) Applicant: Xiamen Fuliye Electric Co., Ltd., Xiamen City (CN)

(72) Inventor: Xiaolin XU, Xiamen City (CN)

(73) Assignee: Xiamen Fuliye Electric Co., Ltd.

(21) Appl. No.: 15/675,676

(22) Filed: Aug. 11, 2017

(30) Foreign Application Priority Data
Aug. 13, 2016 (CN) 201610666367.6

(51) Int. Cl. H03G 3/32; H04S 1/00; H04S 7/00

(52) U.S. Cl. CPC H03G 3/32; H04S 7/30; H04S 1/007; H04S 2400/13

(57) ABSTRACT

A method for synchronizing the left and right channels in smart audio amplifiers for stereo application, where each channel gain is determined by speaker limitation nonlinearly. Gain information is exchanged in real time and a threshold is set such that, if the difference in the gain between the two channels is above the threshold, the gain correction action is taken, and if the difference is below the threshold, it continues to compare the gain of the two channels in the next time frame.

### CROSS-REFERENCE AND RELATED APPLICATION

The subject application claims priority on Chinese patent application No. 201610666367.6 filed on Aug. 13, 2016. The Chinese priority application is incorporated herein by reference.

### TECHNICAL FIELD

The present invention relates to audio amplifier synchronization, particularly, method for two-channel synchronization in an audio amplifier.

### BACKGROUND OF INVENTION

An audio amplifier is a device to amplify audio signals and to drive the speaker. In the application in the stereo, the gain of the left and right channels determines the position information in the audio content. If the distribution of the gain of the two channels varies after amplification, the stereo effect is impacted and the quality of the sound becomes inferior.

In the traditional audio amplifier, the device amplifies the signal according to a preset magnitude of amplification. In the application in the stereo (having both the left and right channels), the two channels have the same gain (that is, the same magnitude of amplification).

As the demand for the sound quality increases in the portable device, the speaker is driven to the extreme. The traditional audio amplifiers are being replaced by the new Smart Audio Amplifiers in the portable device such as the mobile phone. Smart Audio Amplifiers amplify the input signal to the extreme in the displacement of the amplitude of the speaker; as long as the displacement of the amplitude of the speaker still has room, Smart Audio Amplifiers will keep increasing the gain and driving the speaker to the extent that the speaker does not reach the membrane excursion limit or coil temperature limit, thereby getting better sound quality and higher loudness.

As the input signals for the left and right channels differ, the distance to the limit of the speaker differs. At a certain time point, the environment for the speaker may be different in the portable application, for example, the left channel may have larger speaker and better back volume than the right channel, therefore, the two channels may have different gain after Smart Audio Amplified, which will lead to bad user stereo experience.

### SUMMARY OF INVENTION

The present invention provides a solution to synchronize the imbalance in the gain in the application of the Smart Audio Amplifier to ensure good sound quality in the stereo application.

To achieve the objective, the present invention provides a method for synchronizing the left and right channels in the audio amplifier having the following steps:

building communication connection between the left and right channels and exchanging information on the gain in real time;

calculating difference in the gain between the left and right channel and comparing the difference in the value of the gain in the two channels with a preset threshold, if the difference in the value of the gain is above the threshold, adjusting the gain in the left channel, the right channel, or both; if the difference in the value of the gain is below the threshold, continuing to compare the value in the gain of the left and right channels in a next time frame.

In the present invention, I2S (Inter-IC Sound) format is used in the left and right channels.

In the present invention, the threshold value is set to be no more than 2 dB.

In the present invention, the adjustment of the gain is that, when the two channel gain difference is above the threshold, the channel having a higher gain is adjusted to have the same value of the gain as the channel having a lower gain.

In the present invention, the adjustment of gain is that, when the two channel gain difference is above threshold, the channel having a lower gain is adjusted to have the same value of the gain as the channel having a higher gain.

Compared with the current technology in the Smart Audio Amplifier, the method of the present invention is capable of synchronizing the left and right channels by comparing the gain difference to the threshold, thus, solves the imbalance in the volume in the stereo application and brings better user experience while keeping the sound volume.

### BRIEF DESCRIPTION OF THE FIGURE

FIG. 1 is a flow diagram showing the method of the present invention for the left and right channel synchronization in the audio amplifier.

### DETAILED DESCRIPTION OF THE INVENTION AND EMBODIMENT

The present invention is explained in details in the following embodiment in connection with the FIGURE. Experienced engineers in the art may substitute or modify the present invention with routine works without departing from the scope of the present invention under the architecture and principles of the present invention.

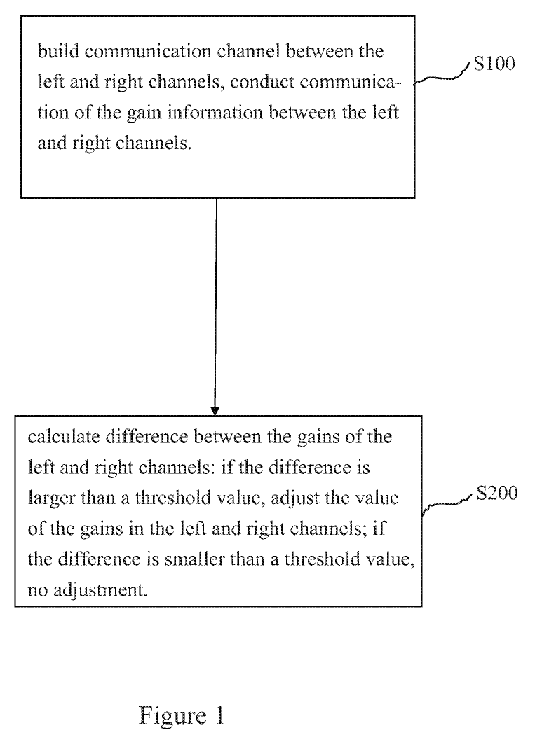

Referring to FIG. 1, the present invention provides a solution to synchronize the left and right channels in the Smart Audio Amplifier. S100 represents the step of building communication protocol between the left and right channels, exchanging the gain information in the left and right channels. S200 represents the step of comparing the gain difference between the left and right channels, and if the difference is higher than a threshold, then, the gain is adjusted, and if the difference is less than the threshold, then, it continues to compare in the next time frame without adjustment.

In details, I2S(Inter-IC Sound) format is used in the communication between the two channels. I2S is the standard digital audio format and contains the gain info. In the communication, the left channel may pass gain information to the right channel, and the right channel may also pass the gain information to the left channel.

During the comparison of the gain, if the difference in the gain of the two channels is higher than the threshold, then, the gain of the channel having the higher gain is reduced to be the same as the gain of the channel having the lower gain. Normally, the threshold may be set to 2 dB, however, in the real life, when the size of the speaker, back volume, environment temperature, etc., are considered, the threshold may be set to a value that is less than 2 dB.

Normally, the coil temperature of the speaker limits the speaker, thus, to synchronize the higher channel to the lower channel works for the safety of the speaker.

However, in some ideal cases where robust speakers are applied, it is also possible to synchronize the lower gain channel to the higher gain channel for better sound experience.

In summary, the method of the present invention is to establish communication between the left and right channels to exchange gain information through the I2S protocol. If the gain difference is bigger than the threshold, then, actions are taken to synchronize, otherwise, it continues for the next time frame.

The embodiment is for illustrating an application of the present invention and should not be taken to limit the scope of the present invention.

I claim:

1. A method for synchronizing a left channel and a right channel in a smart audio amplifier, comprising
building a communication channel between a left channel and a right channel,
exchanging gain information of the left channel and the right channel in real time,
calculating difference in the gain between the left channel and the right channel and comparing the difference with a set threshold, and
adjusting the gain when the difference is above the threshold, or continuing to compare in a next time frame when the difference is below the threshold.

2. The method of claim 1, wherein the communication channel is built in a communication protocol that is in I2S format.

3. The method of claim 1, wherein value of the set threshold is 2 Db.

4. The method of claim 1, wherein the channel having the higher gain is adjusted to have the same gain as the channel having the lower gain when the difference is above the threshold.

5. The method of claim 1, wherein the channel having the lower gain is adjusted to have the same gain as the channel having the higher gain when the difference is above the threshold.
